(19) United States
(12) Patent Application Publication
(10) Pub. No.: US 2010/0000771 A1
(43) Pub. Date: Jan. 7, 2010

(54) COPPER-CLAD LAMINATE, PRINTED-WIRING BOARDS, MULTILAYER PRINTED-WIRING BOARDS, AND METHOD FOR MANUFACTURING THE SAME

(75) Inventors: Koichi Shimauchi, Hyogo (JP); Hirofumi Ito, Ibaraki (JP); Jeong Chang Lee, Shizuoka (JP)

Correspondence Address: Workman Nydegger;1000 Eagle Gate Tower, 60 East South Temple, Salt Lake City, UT, 84111, US

(73) Assignees: Nippon Pillar Packing Co., Ltd., Osaka (JP); Junkosha Inc., Kasama-shi, Ibaraki (JP); DuPont-Mitsui Fluorochemicals Co., Ltd., Tokyo (JP)

(21) Appl. No.: 12/088,612

(22) PCT Filed: Sep. 21, 2006
(86) PCT No.: PCT/JP2006/318757

§ 371 Date: Jun. 26, 2009

(30) Foreign Application Priority Data
Sep. 30, 2005 (JP) 2005-289419

(51) Int. Cl. H05K 1/09; B32B 37/12; B32B 27/30; D03D 15/00

(52) U.S. Cl. 174/257; 156/327; 428/422; 442/232

(57) ABSTRACT

The present invention is to significantly improve copper-foil adhesion strength (copper-foil peel strength) without roughening or blackening a copper-foil surface, and thereby to provide a copper-clad laminate used favorably in a high frequency range. The copper-clad laminate (101) for a single-sided printed-wiring board is formed by bonding a copper foil (4) onto a surface of an insulating substrate (2) with an LCP/PFA composite film (3) disposed in between. The insulating substrate (2) is made of a fluororesin prepreg 2A. The copper foil (4) is a rolled copper foil, the both surfaces of which are smooth and not roughened or blackened. The insulating substrate (2) and the copper foil (4) are bonded to each other with the composite film (3) disposed in between by firing and pressing them under temperature conditions which are 5° C. to 40° C. higher than the melting point of PFA and lower than the melting point of LCP.

### TECHNICAL FIELD

The present invention relates to a copper-clad laminate, which is formed by bonding a copper foil onto a fluororesin insulating substrate with an adhesive resin film disposed in between, for a printed-wiring board which can suitably be used in a high frequency range. In addition, the present invention also relates to a method for manufacturing the same, and a printed-wiring board and a multilayer printed-wiring board which include the copper-clad laminate, and a method for manufacturing the same.

### BACKGROUND OF THE INVENTION

A copper-clad laminate formed by bonding a copper foil onto a fluororesin insulating substrate, and a printed-wiring board and a multilayer printed-wiring board which include the copper-clad laminate can suitably be used in a high frequency range of G (giga) Hz or more due to the characteristics such as a small dielectric tangent (tan d) of a fluororesin which is a dielectric layer construction material.

As such a copper-clad laminate, well-known is a copper-clad laminate formed by bonding a copper foil onto an insulating substrate (fluororesin prepreg) with an adhesive resin film disposed in between. Here, a PFA film is used as the adhesive resin film (see, for example, paragraph [0012] or paragraphs [0024] to [0026] of Patent Document 1).

The adhesion of a copper foil with the adhesive resin film is obtained mainly with the anchoring effect of the irregularity of the adhesion surface of the copper foil. The larger the irregularity (surface roughness) of the adhesion surface of the copper foil is, the larger adhesion (peel strength of the copper foil) can be obtained. Accordingly, an electrolytic copper foil having a higher surface roughness than that of a rolled copper foil is generally used as the copper foil (see, for example, paragraph [0026] of Patent Document 1). A matte surface (M surface) having a higher surface roughness than that of a glossy shiny surface (S surface) is used as an adhesion surface. When the irregularity of an adhesion surface (M surface) is so small that sufficient adhesion cannot be obtained, the M surface is roughened by, for example, etching. The rolled copper foil has less crystal grain boundaries than an electrolytic copper foil, and therefore has excellent bending resistance, thus being used in a copper-clad laminate for a flexible printed-wiring board in some cases. However, the rolled copper foil cannot exhibit a sufficient anchoring effect because of its low surface roughness on both surfaces, hardly withstands an adequate roughening process to exhibit an effective anchoring effect, and experiences an adverse effect by an excessive roughening process. As a result, a frequency of practical use of the rolled copper foil is very low as compared to that of the electrolytic copper foil. A similar roughening processing (blackening) to that described above is also performed on the copper foil in a multilayer printed-wiring board formed by laminating multiple printed-wiring boards (single-sided printed-wiring boards). Specifically, the blackening (black oxide treatment) is performed on the copper-foil surface of one printed-wiring board while the copper-foil surface is to be bonded onto the base material surface of the other printed-wiring board. By performing the blackening, needle-like fine objects are formed on the copper-foil surface (the S surface when an electrolytic copper foil is used) so that the copper-foil surface can exhibit an anchoring effect.

### Patent Document 1: Japanese Patent Application Laid-Open No. 2002-307611

### DISCLOSURE OF THE INVENTION

However, when one surface or both surfaces are roughened as described above by a roughening or blackening processing to enhance the adhesion (peel strength) of a copper foil, the transmission loss is increased, resulting in the deterioration in characteristics and reliability in a high frequency range.

That is, a high frequency current has a skin effect as its peculiar phenomenon. The skin effect is a phenomenon in which a larger amount of current is concentrated in a surface part of a conductor by higher frequency. The current density is reduced at a deeper depth from the surface part. A depth providing 1/e (e is a natural logarithm) of the current density value on the surface is referred to as a skin depth, and serves as an indication of a depth at which a current flows. The skin depth depends on frequency, and is reduced as frequency is increased.

Therefore, when a copper foil having one or both surfaces which are roughened as described above is used, a current is concentrated on the surface part according to the skin effect as the frequency is increased, resulting in the increase in skin resistance. As a result, not only is the current loss increased, but the current also flows on the irregular surface of the conductor when the skin depth is smaller than that of the surface irregularity of the conductor. Consequently, the transmission distance is increased, resulting in the increase in the time required for signal transmission and also in a current loss.

As described above, for the conventional fluororesin copper-clad laminate, the roughening or blackening of its copper-foil surface is indispensable to ensure adhesion strength. Accordingly, with the conventional fluororesin copper-clad laminate, an energy loss in a high frequency signal and the distortion of the waveform of the signal cannot be avoided. Consequently it has been a reality that an advantage of the excellent particular characteristics (low dielectric constant and low dielectric tangent characteristic in a high frequency band) of a fluororesin cannot sufficiently be utilized. An IVH (inner via hole) and/or BVH (blind via hole) are formed in a multilayer printed-wiring board to increase circuit density. However, when a PFA film is used as an adhesive resin film, the molding temperature is necessary to be increased to 380° C. or more (see, for example, paragraph [0026] of Patent Document 1). For this reason, the IVH and/or BVH could be damaged when a laminate of a printed-wiring board is molded by heating. It is therefore difficult to obtain a multilayer printed-wiring board having the IVH and/or BVH.

The present invention has been made in view of the above problems. An object of the present invention is to provide: a printed-wiring board and a multilayer printed-wiring board which have a significantly improved copper-foil adhesion (copper-foil peel strength) without a roughening or blackening process performed on its copper-foil surface, and thus which can be used favorably in a high frequency range; a copper-clad laminate which can suitably be used as the construction base member of these boards; and a method for favorably manufacturing these.

The present invention proposes a copper-clad laminate characterized in that it is formed by first bonding a copper foil onto a fluororesin insulating substrate with a composite film disposed in between. The copper foil used here has surfaces which are smooth and not roughened or blackened. The composite film (hereinafter referred to as “LCP/PFA composite film”) is formed of the blend of a small amount of tetrafluoroethylene perfluoroalkylvinylether copolymer having a functional group (PFA) (A) and liquid crystal polymer resin (LCP) (B) and a large amount of PFA having no functional group (C). Here, the PFA having a functional group means a PFA having a side-chain functional group or a functional group which is connected to the side-chain thereof. The functional group includes an ester, an alcohol, an acid (including carbonic acid, sulfuric acid, and phosphoric acid), salt, and a halide of these. The other functional group includes cyanide, carbamate, and nitrile. A particular functional group which can be used includes “—SO₂F”, “—CN”, “—COOH”, and “—CH₂-Z” (Z is “—OH”, “—OCN”, “—O—(CO)—NH₂”, or “—OP(O)(OH)₂”). A preferred functional group includes “—SO₂F”, and “—CH₂-Z” (Z is “—OH”, “—O—(CO)—NH₂”, or “—OP(O)(OH)₂”). Of these, a functional group “—CH₂-Z” containing “—OH”, “—O—(CO)—NH₂”, or “—OP(O)(OH)₂” as “-Z” is particularly preferable.

In a preferred embodiment of such a copper-clad laminate, an insulating substrate is made of a prepreg formed by impregnating a fluororesin into a fibrous reinforcement member. A woven glass fabric (for example, E glass (aluminosilicate glass) cloth) is preferably used as the fibrous reinforcement member. PTFE (polytetrafluoroethylene) is preferably used as the fluororesin which is impregnated into the glass wove fabric. An unroughened copper foil having surface roughness (center line average roughness specified in JIS-B-0601) Ra of 0.2 μm or less is preferably used as a copper foil. In general, a rolled copper foil having surfaces which are smooth and not roughened or blackened, is preferably used.

The LCP/PFA composite film is used as a adhesive resin film to bond a copper foil onto a prepreg, and obtained by extrusion-molding a mixture of, for example, 1% to 20% by mass of PFA having a functional group, 1% to 15% by mass of LCP, and 65% to 98% by mass of PFA having no functional group in the form of a film having a thickness of about 10 to 30 μm. To be specific, “SILKY BOND” available from Junkosha Inc. is preferred. A copper foil is bonded onto the both surfaces or one surface of a prepreg insulating substrate with the above described adhesive resin film disposed in between corresponding to an application.

The present invention secondly proposes a printed-wiring board characterized in that it uses the above described copper-clad laminate as the construction base member thereof, and is manufactured by forming a predetermined conductor pattern on the copper-foil surface of the laminate. The printed-wiring board is roughly classified corresponding to an application into a double-sided printed-wiring board in which a conductor pattern is formed on the both surfaces of the copper-clad laminate, and a single-sided printed-wiring board in which a conductor pattern is formed on the one surface of the copper-clad laminate.

The present invention thirdly proposes a multilayer printed-wiring board formed by laminating a plurality of the above described single-sided printed-wiring boards. Such a multilayer printed-wiring board is formed by bonding the base material surface of each single-sided printed-wiring board onto the copper-foil surface of a corresponding single-sided printed-wiring board facing the above base material surface with the above described LCP/PFA composite film disposed in between by heating without blackening the copper-foil surfaces. As described below, a firing temperature (molding temperature) for bonding an insulating substrate onto a copper foil with the LCP/PFA composite film is 340° C. to 345° C. This temperature is so low that the multilayer printed-wiring board can have an IVH (inner via hole) and/or a BVH (blind via hole). That is, when a PFA film is used as an adhesive resin film, a molding temperature needs to be 380° C. or more (see, for example, paragraph [0026] of Patent Document 1). Consequently, such high temperature processing could cause the IVH and the BVH to be damaged. However, when using an LCP/PFA composite film as an adhesive resin film, the above problems do not arise because the LCP/PFA composite film has an extremely high fluidity due to LPC, resulting in the possibility to reduce a molding temperature (5° C. to 40° C. higher than the melting point of PFA and lower than the melting point of LCP).

The present invention fourth proposes a method for producing the above described copper-clad laminate, the printed-wiring board, and the multilayer printed-wiring board.

That is, in a method for producing the copper-clad laminate, a copper foil is bonded onto an insulating substrate made of a prepreg formed by impregnating a fluororesin into a fibrous reinforcement member, or a laminated prepreg formed by laminating multiple prepregs with the LCP/PFA composite film by heating and pressing them under a temperature condition of 5° C. to 40° C. higher than the melting point of PFA and lower than the melting point of LCP. The copper foil has surfaces which are smooth and not roughened or blackened. A copper foil is bonded onto the both surface or the one surface of an insulating substrate with an LCP/PFA composite film disposed in between. In a method for producing a printed-wiring board, a copper-clad laminate is manufactured by bonding a copper foil onto the both surfaces or the one surface of an insulating substrate in the above manner, and a predetermined conductor pattern is subsequently formed on the copper-foil surface of the copper-clad laminate. The conductor pattern is formed by a well-known method such as subtractive method. In a method for producing a multilayer printed-wiring board, multiple sheets of single-sided printed-wiring boards formed by bonding a copper foil onto the one surface of an insulating substrate in the above manner are manufactured, and these single-sided printed-wiring boards are then bonded onto each other while laminating them and placing an LCP/PFA composite film between the base material surface of each single sided printed-wiring board and the copper-foil surface (not blackened) of a corresponding single sided printed-wiring board facing the above base material surface by heat (firing)- and pressure-molding them under a temperature condition of 340° C. to 345° C.

The LPC/PFA composite film also exhibits extremely high adhesion properties to a copper-foil surface having a smooth surface that is not roughened or blackened. The reason is because:

(1) LCP, super engineering plastic which shows liquid crystal properties while being in a molten state, has a high heat resistance, good fluidity, and high solidification strength, resulting in a very high fluidity of the LCP/PFA composite film as compared to a general adhesive resin film (such as a PFA film) when it is molten;
(2) fine irregularity is present on a copper-foil surface in which the surface is not roughening-processed or blackening-processed;
(3) the molten material of the LCP/PFA composite film effectively permeates the fine irregularity on the copper-foil surface to exhibit a large anchoring effect because of points described in the above (1) and (2); and
(4) the stiffness of the LCP/PFA composite film during melt-solidification is very high as compared to that of a general adhesive resin film.

Therefore, the use of the LCP-PFA composite film as an adhesive resin film allows extremely high copper adhesion strength (copper foil peel strength) to be obtained even when a copper foil adhesion surface (the both surfaces of a copper foil in a multilayer printed-wiring board) is a smooth surface which is not roughened or blackened.

According to the present invention, the adhesion strength (peel strength) of a copper foil can previously be increased without roughening or blackening a copper-foil surface. Therefore, a conductor loss caused by the irregularity of a copper-foil surface can be reduced. Consequently, a copper-clad laminate, a printed-wiring board and multilayer printed-wiring board which are suitable for practical use, and therefore can suitably be used in a high frequency range can be provided.

In addition, a large peel strength can be obtained even when a copper foil (copper foil having low surface roughness) not subjected to roughening processing is used. Therefore, etching is not necessary to be excessively performed, and the fine pattern of a circuit copper foil can easily be realized. Furthermore, practicability can be exhibited in a TAB tape area. Moreover, the blackening of a copper-foil surface (copper-foil surface connected to a substrate) between layers is not necessary in producing a multilayer printed-wiring board, resulting in the possibility to significantly simplify the production process. In addition, a multilayer printed-wiring board in which an IVH and/or a BVH are suitably formed can easily be obtained unlike the use of the conventional fluororesin copper-clad laminate because a low molding temperature can be used.

Furthermore, a rolled copper foil having a smaller crystal grain boundary than an electrolytic copper foil, and having excellent bending resistance can be used as a copper foil in an unroughened form. Consequently, a flexible printed-wiring board suitable for practical use can be provided, as a fluororesin prepreg having excellent stretch and toughness as compared to a thermosetting resin prepreg such as epoxy resin is used as an insulating substrate.

### BRIEF DESCRIPTION OF DRAWINGS

FIG. 1 is a longitudinal side elevational view showing the main part of the first copper-clad laminate;

FIG. 2 is a longitudinal side elevational view showing the main part of the second copper-clad laminate;

FIG. 3 is a longitudinal side elevational view showing the main part of the third copper-clad laminate; and

FIG. 4 is a longitudinal side elevational view showing the main part of the fourth copper-clad laminate.

### DESCRIPTION OF SYMBOLS

2 Insulating substrate
2A Prepreg
2a Fibrous reinforcement member (woven glass fabric)
2b Fluororesin (PTFE)
3 LCP/PFA composite film
4 Copper foil (rolled copper foil)
101 First copper-clad laminate
102 Second copper-clad laminate
103 Third copper-clad laminate
104 Fourth copper-clad laminate

### DETAILED DESCRIPTION OF PREFERRED EMBODIMENTS

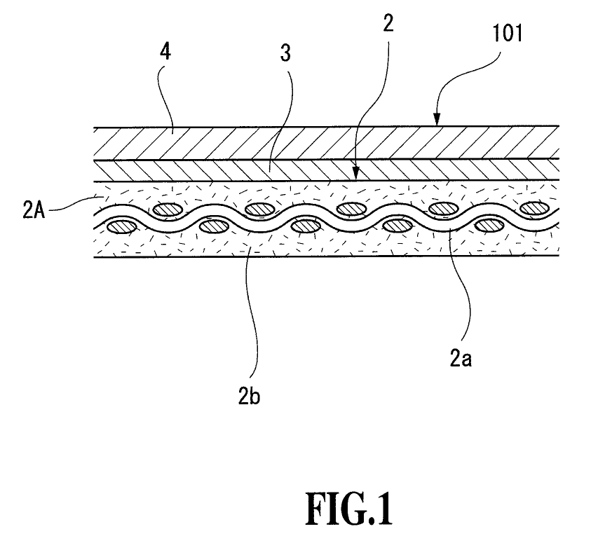

FIGS. 1 to 4 each are a longitudinal side elevational view showing the main part of the copper-clad laminate related to the present invention.

The copper-clad laminate 101 (hereinafter referred to as “first copper-clad laminate”) shown in FIG. 1 is a copper-clad laminate for a single-sided printed-wiring board. T copper-clad laminate 101 is formed by bonding a copper foil 4 onto the one surface of an insulating substrate 2 made of a fluororesin prepreg 2A with an LCP/PFA composite film 3 disposed in between.

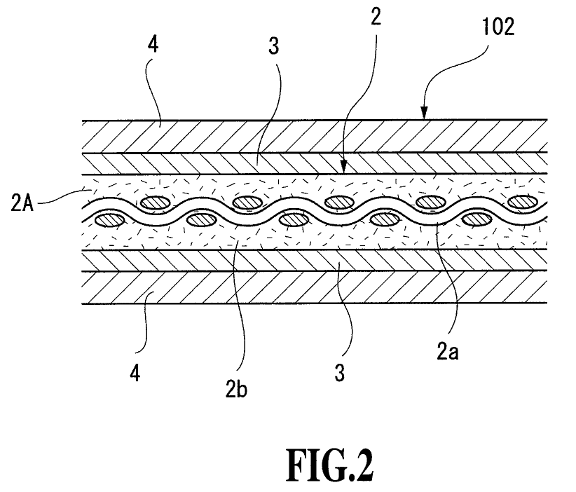

The copper-clad laminate 102 (hereinafter referred to as “second copper-clad laminate”) shown in FIG. 2 is a copper-clad laminate for a double-sided printed-wiring board, which is formed by bonding a copper foil 4 onto each of the both surfaces of an insulating substrate 2 with an LCP/PFA composite film 3 disposed in between. The insulating substrate 2 is made of a planar prepreg 2A formed by impregnating fluororesin 2b into a fibrous reinforcement member 2a.

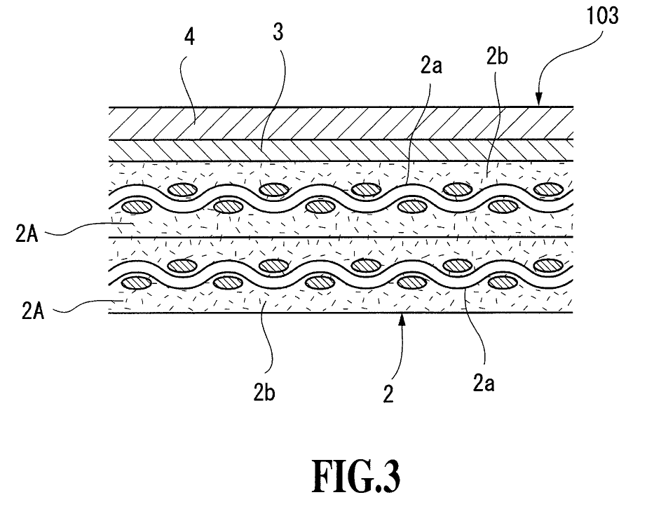

The copper-clad laminate 103 (hereinafter referred to as “third copper-clad laminate”) shown in FIG. 3 is a copper-clad laminate for a single-sided printed-wiring board, which is formed by bonding a copper foil 4 onto a surface of an insulating substrate 2 with an LCP/PFA composite film 3 disposed in between. The insulating substrate 2 is made by laminating multiple (two in the example shown in FIG. 3) planar prepregs 2A . . . , each formed by impregnating fluororesin 2b into a fibrous reinforcement member 2a.

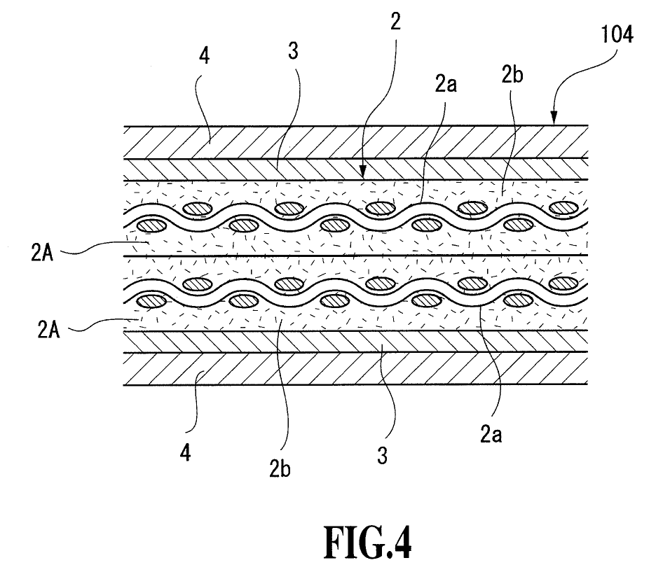

The copper-clad laminate 104 (hereinafter referred to as “fourth copper-clad laminate”) shown in FIG. 4 is a copper-clad laminate for a double-sided printed-wiring board, which is formed by bonding a copper foil 4 to each of the both surfaces of the insulating substrate 2 with an LCP/PFA composite film 3 disposed in between. The insulating substrate 2 is made by laminating multiple (two in the example shown in FIG. 4) planar prepregs 2A . . . , each formed by impregnating fluororesin 2b into a fibrous reinforcement member 2a.

As the copper foil 4 for each of the copper-clad laminates 101, 102, 103, and 104, used is a copper foil having both surfaces being smooth and not roughened (or blackened). (A copper foil having a roughness Ra of the both surfaces of 0.2 μm or less is preferable). For example, an unroughened rolled copper foil manufactured by rolling and annealing an electrolytic copper or the like is preferably used. An electrolytic copper foil is not preferable to use because one of its surfaces (M surface) is roughened in production. However, an electrolytic copper foil can be used as a copper foil 4 if the M surface is smoothened (for example, surface roughness Ra: 0.2 μm or less) by electric or chemical processing.

The LCP/PFA composite film 3 is obtained by extrusion-molding a mixture of, for example, 1% to 20% by mass of PFA having a functional group, 1% to 15% by mass of LCP, and 65% to 98% by mass of PFA having no functional group in the form of a film having a thickness of about 10 to 30 μm. To be specific, “SILKY BOND” available from Junkosha Inc. is preferable. The LCP/PFA composite film 3 has an extremely high fluidity, and can exhibit a sufficient anchoring effect to a micro-scaled irregularity even when a copper foil adhesion surface is smooth (for example, surface roughness Ra: 0.2 μm or less), resulting in the possibility to obtain high copper-foil adhesion strength (copper-foil peel strength).

A prepreg 2A is formed by impregnating a fluororesin 2b into a fibrous reinforcement member 2a in the example shown in a figure. As a fibrous reinforcement member 2a, a woven glass fabric such as E glass (aluminosilicate glass) cloth is used, in addition, nonwoven glass fabric and nonwoven aramid fabric can be used. As a fluororesin 2b, tetrafluoroethylene polymer (PTFE), tetrafluoroethylene hexafluoropropylene copolymer, tetrafluoroethylene perfluoro(alkylvinylether)copolymer (PFA), tetrafluoroethylene ethylene copolymer, polychlorotrifluoroethylene, ethylene chlorotrifluoroethylene copolymer, polyvinylidene-fluoride, vinylidene-fluoride hexafluoropropylene copolymer, or polyvinyl fluoride can be used, and in particular PTFE is preferably used. A prepreg 2A is obtained by alternately repeating a process of impregnating the dispersion of the fluororesin 2b into the fibrous reinforcement member 2a, and a process of drying the same at a temperature lower than the melting point of fluororesin.

Each of the copper-clad laminates 101, 102, 103, and 104 is obtained by laminating one or more prepregs 2A, one or more LCP-PFA composite films 3 and one or more copper foils 4 in the manner shown in FIGS. 1, 2, 3 and 4, respectively, by then firing and pressure-molding the resultant laminate under temperature conditions of from 340° C. to 345° C.

The printed-wiring board according to the present invention is manufactured by forming a predetermined conductor pattern on each of the copper-foil surfaces of the copper-clad laminates 101, 102, 103 and 104. The conductor pattern is formed by using a normal method (subtractive method or the like). A single-sided printed-wiring board is obtained by forming a conductor pattern on one of the surfaces of the first or third copper-clad laminate 101 or 103. A double-sided printed-wiring board is obtained by forming a conductor pattern on each of the both surfaces of the second or third copper-clad laminate 102 or 104.

The multilayer printed-wiring board according to the present invention is manufactured by laminating multiple single-sided printed-wiring boards (printed-wiring boards manufactured by forming a conductor pattern on one of the surfaces of the first or third copper-clad laminates 101 or 103). Specifically, the multilayer printed-wiring board is obtained by disposing an LCP/PFA composite film between the base material surface of each single-sided printed-wiring board and the copper-foil surface of a corresponding single-sided printed-wiring board facing the above base material surface, and then by firing and pressure-molding them under temperature conditions of from 340° C. to 345° C. It goes without saying that, in such a case, roughening processing such as blackening is not performed on each of the copper-foil surfaces bonded onto the base material surfaces.

### EXAMPLES

As an example, the following copper-clad laminates No. 1 and No. 2 were manufactured.

That is, the first prepreg having a PTFE resin impregnation ratio of 91.5% and a thickness of 130 nm was obtained by alternately repeating a process of impregnating a PTFE dispersion having a concentration of 60% into an E glass cloth having a basis weight of 24 g/m², and a process of drying the same under a temperature condition of 305° C., which is less than the melting point of PTFE (327° C.). Five of the first prepregs were manufactured in total including four of the first prepregs used in the comparative examples described below.

In addition, the second prepreg having a PTFE resin impregnation ratio of 91.5% was obtained by alternately repeating a process of impregnating a PTFE dispersion having a concentration of 60% into an E glass cloth having a basis weight of 12 g/m², and a process of drying the same under a temperature condition of 305° C., which is less than the melting point of PTFE (327° C.). Two second prepregs were manufactured.

The copper-clad laminate No. 1 equivalent to the second copper-clad laminate 102 (see FIG. 2) was manufactured by bonding a copper foil onto the both surfaces of the first prepreg. Specifically, the copper-clad laminate No. 1 was obtained as follows. An LCP/PFA composite film (“SILKY BOND” available from Junkosha Inc.) having a thickness of 15 μm is laminated on each of the both surfaces of the first prepreg. Then, a copper foil having a thickness of 18 μm is further laminated on each of the LCP/PFA composite films. Finally, the resultant laminate is fired and pressure-molded under the following conditions: a firing temperature of 345° C., firing time of 15 minutes, a molding surface pressure of 2 MPa, and a reduced-pressure atmosphere of 10 to 20 hPa. A rolled copper foil, the both surfaces of which are smooth and not roughened (surface roughness Ra: 0.2 μm), was used as a copper foil.

The copper-clad laminate No. 2 equivalent to the fourth copper-clad laminate 104 (see FIG. 4) was manufactured by laminating two second prepregs, and by then bonding a copper foil onto the both surfaces of the laminated prepreg. Specifically, the copper-clad laminate No. 2 was obtained as follows. An LCP/PFA composite film (“SILKY BOND” available from Junkosha Inc.) having a thickness of 15 μm is laminated on each of the both surfaces of the laminated prepreg. Then, a copper foil having a thickness of 18 μm is further laminated on each of the LCP/PFA composite films. Finally, the resultant laminate is fired and pressure-molded under the following conditions: a firing temperature of 345° C., firing time of 15 minutes, a molding surface pressure of 2 MPa, and a reduced-pressure atmosphere of 10 to 20 hPa. A rolled copper foil, the both surfaces of which are smooth and not roughened (surface roughness Ra: 0.2 μm), was used as a copper foil. The copper-clad laminate No. 2 has the same construction as that of the first copper-clad laminate No. 1 except that a laminate formed by laminating two second prepregs (laminated prepreg) was used as an insulating substrate.

Copper-clad laminates No. 11 to No. 14 formed by bonding a copper foil onto each of the both surfaces of a first prepreg obtained in the above manner were manufactured as comparative examples.

That is, the copper-clad laminate No. 11 is the one obtained by laminating the same copper foil (rolled copper foil having both surfaces which were smooth and not roughened) as that used in the example on each of the both surfaces of the first prepreg, and by then firing and pressure-molding the resultant laminate under the following conditions: a firing temperature of 385° C., firing time of 30 minutes, a molding surface pressure of 2 MPa, and a reduced-pressure atmosphere of 10 to 20 hPa. The copper-clad laminate No. 11, obtained by directly bonding a copper foil onto the first prepreg without disposing an adhesive resin film in between, has the same construction as that of the copper-clad laminate No. 1 except that an LCP/PFA composite film is not used.

The copper-clad laminate No. 12 is the one obtained by laminating a PFA film having a thickness of 25 μm on each of the both surfaces of the first prepreg, by laminating the same copper foil (rolled copper foil having the both surfaces which were smooth and not roughened) as that used in the example on each of the PFA films, and by then firing and pressure-molding the laminate under the following conditions: a firing temperature of 370° C., firing time of 30 minutes, a molding surface pressure of 2 MPa, and a reduced-pressure atmosphere of 10 to 20 hPa. The copper-clad laminate No. 12 has the same construction as that of the copper-clad laminate No. 1 except that a PFA film is used as an adhesive resin film.

The copper-clad laminate No. 13 is the one obtained by laminating the same LCP/PFA composite film as that used in the example on each of the both surfaces of the first prepreg, by further laminating a low-profile electrolytic copper foil having a thickness of 18 μm on each of the LCP/PFA composite films while causing the roughened surface (M surface) to contact the LCP-PFA composite film, and by then firing and pressure-molding the laminate under the same conditions (firing temperature: 345° C., firing time: 15 minutes, molding surface pressure: 2 MPa, reduced-pressure atmosphere: 10 to 20 hPa) as these of the example. The copper-clad laminate No. 13 has the same construction as that of the copper-clad laminate No. 1 except that a low-profile electrolytic copper foil is used as a copper foil. The surface roughness of the M surface (bonding surface) of the low-profile electrolytic copper foil Ra is 1 μm.

The copper-clad laminate No. 14 is the one obtained by laminating the same LCP/PFA composite film as that used in the example on each of the both surfaces of the first prepreg, by further laminating an electrolytic copper foil having a thickness of 18 μm on each of the LCP/PFA composite films while causing the roughened surface (M surface) to contact the LCP-PFA composite film, and by then firing and pressure-molding the laminate under the same conditions (firing temperature: 345° C., firing time: 15 minutes, molding surface pressure: 2 MPa, reduced-pressure atmosphere: 10 to 20 hPa) as these of the example. The copper-clad laminate No. 14 has the same construction as that of the copper-clad laminate No. 1 except that an electrolytic copper foil is used as a copper foil. The surface roughness of the M surface (adhesion surface) of the electrolytic copper foil Ra is 1 μm.

The copper peel strength (N/cm) of copper-clad laminates No. 1, No. 2, and No. 11 to No. 14 obtained in the above manner was measured by a test method of a copper-clad laminate for a printed-wiring board according to JIS C6481. The measurement results are as shown in Table 1.

As seen from Table 1, the copper-clad laminates No. 1 and No. 2 of examples have much higher peel strength than that of the copper-clad laminates No. 11 and No. 12 of the comparative example. Specifically, the copper-clad laminates No. 11 and No. 12 have low surface roughness on the unroughened adhesion surface of the rolled copper foil, and therefore have low peel strength when an adhesive resin film (PFA film) is used as in the copper-clad laminate No. 12 as well as when an adhesive resin film is not used as in the copper-clad laminate No. 11. However, the copper-clad laminates No. 1 and No. 2 have extremely high peel strength even though an unroughened rolled copper foil is used as in the copper-clad laminates No. 11 and No. 12. Therefore, it is understood that high peel strength is obtained even in a smooth adhesion surface of a copper foil having low surface roughness by using an LCP/PFA composite film as an adhesive resin film. In particular, the copper-clad laminate No. 2, in which a laminate formed of two sheets of the second prepreg (laminated prepreg) is used as an insulating substrate, has very high peel strength as compared to the copper-clad laminate No. 1, in which one sheet of the first prepreg is used as an insulating substrate. This is considered to be because the second prepreg, in which a glass cloth having a smaller basis weight (12 g/m²) than the first prepreg is used, has a low irregularity of the cloth, and because the insulating substrate is formed by laminating two second prepregs, and therefore exhibits high cushioning properties in pressure-molding (in bonding), resulting in the uniform application of a molding pressure on the entire surface of the laminate. In copper-clad laminates No. 13 and No. 14 in which the adhesion surface of a copper foil is roughened (M surface), the adhesion by means of an LCP-PFA composite film works due to an anchoring effect on the adhesion surface. Therefore, high copper foil peel strength is naturally obtained. In the copper-clad laminate No. 2, copper foil peel strength equivalent to that of the copper-clad laminates No. 13 and No. 14 is obtained even though the copper-clad laminate No. 2 has the smooth adhesion surface of the copper foil. Accordingly, it is understood that higher copper foil peel strength is obtained even when a copper foil having smooth both surfaces is used, by using the laminated prepreg as in the copper-clad laminate No. 2 as an insulating substrate. That is, the further improvement of copper foil peel strength can be achieved by previously constructing an insulating substrate of a laminated prepreg as well as using an LCP/PFA composite film as an adhesive resin film.

The relative dielectric constant ξr of the copper-clad laminates No. 1, No. 2, No. 13, and No. 14 was measured by a disc resonator strip line method. The obtained results are as shown in Table 1. It is understood that an LCP/PFA composite film does little to reduce the superiority (low dielectric constant characteristic) of a fluororesin insulating substrate. The dielectric loss tangent (tan d) of the copper-clad laminate No. 1 of the Example was measured by a disc resonator strip line method. At the same time, the thickness and the heat resistance were measured according to JIS C6481. The obtained results are: tan d (10 GHz): 7.528×10⁻⁴; thickness: 0.188 mm; solder heat resistance (normal state): no change; solder heat resistance (pressure cooker): no change; water absorption coefficient (normal state): 0.024%; heat resistance: no change; surface resistance (normal state): 5.6×10¹⁴ Ω; surface resistance (moisture absorbable state): 3×10¹⁴ Ω; volume resistance (normal state): 1.2×10¹⁷ Ω·cm; volume resistance (moisture absorbable state): 9.7×10¹⁶ Ω·cm. It was recognized that the superiority of the use of an unroughened rolled copper foil and fluorine insulating substrate (including LCP/PFA composite film) is secured.

The Qu value (inverse of the total value of a conductor layer loss and a dielectric material layer loss) of the copper-clad laminates No. 1 and No. 2 of the Example, and the copper-clad laminates No. 13, and No. 14 of the Comparative example was measured. The obtained results are as shown in Table 1. A larger Qu value was measured with the copper-clad laminates No. 1 and No. 2 than with the copper-clad laminates No. 13 and No. 14.

In the copper-clad laminates No. 1, No. 2, No. 13, and No. 14, the same quality insulating substrate (fluororesin prepreg) and the same quality adhesive resin film (LCP/PFA composite film) are used. Therefore, they naturally have the same dielectric material layer loss. Accordingly, it is understood that the copper-clad laminates No. 1 and No. 2 having a larger Qu value than the copper-clad laminates No. 13 and No. 14 has a small conductor layer loss. That is, the use of a copper foil (unroughened rolled copper foil) having the smooth both surfaces causes a conductor layer loss to significantly be reduced like the copper-clad laminates No. 1 and No. 2 as compared to the use of the electrolytic copper foil having high surface roughness like the copper-clad laminates No. 13 and No. 14. Therefore, it is understood that a printed-wiring board and a multilayer printed-wiring board which can suitably be used in a high frequency range can be obtained by using, as a construction base member, a copper-clad laminate formed by bonding a copper foil having the smooth both surfaces with an LCP/PFA composite film disposed in between.

TABLE 1

| | | copper-foil | relative | |
|---|---|---|---|---|
| | | peel | dielectric | |
| | copper-clad, | strength | constant | Qu |
| | laminate | (N/cm) | (ξr) | value |
| Example | No. 1 | 11.3 | 2.17 | 576 |
| | No. 2 | 26.1 | 2.17 | 590 |
| Comparative | No. 11 | 2.45 | — | — |
| example | No. 12 | 0.98 | — | — |
| | No. 13 | 26.1 | 2.18 | 497 |
| | No. 14 | 25.8 | 2.18 | 290 |

1. A copper-clad laminate comprising a copper foil bonded onto a fluororesin insulating substrate with an LCP/PFA composite film disposed in between, both surfaces of the copper foil being smooth and not roughened or blackened.

2. The copper-clad laminate according to claim 1, wherein the insulating substrate is made of a prepreg formed by impregnating a fluororesin into a fibrous reinforcement member.

3. The copper-clad laminate according to claim 2, wherein:
the fibrous reinforcement member is a woven glass fabric, and
the fluororesin impregnated into the fibrous reinforcement member is PTFE.

4. The copper-clad laminate according to claim 1, wherein the copper foil is a rolled copper foil.

5. The copper-clad laminate according to claim 1, wherein the copper foil is bonded onto the both surfaces of the insulating substrate with the composite film disposed in between.

6. The copper-clad laminate according to claim 1, wherein the copper foil is bonded onto a surface of the insulating substrate with the composite film disposed in between.

7. A printed-wiring board manufactured by forming predetermined conductor patterns on the copper-foil surfaces of the copper-clad laminate according to claim 5.

8. A printed-wiring board manufactured by forming a predetermined conductor pattern on the copper-foil surface of the copper-clad laminate according to claim 6.

9. A multilayer printed-wiring board manufactured by laminating the printed-wiring boards according to claim 8, wherein the base material surface of each printed-wiring board is bonded onto the copper-foil surface of a corresponding printed-wiring board facing the above base material surface, with the LCP/PFA composite film disposed in between without blackening the copper-foil surface.

10. The multilayer printed-wiring board according to claim 9, wherein at least one of an IVH and a BVH is formed.

11. A method for manufacturing a copper-clad laminate, the method comprising bonding an insulating substrate and a copper foil with an LCP/PFA composite film disposed in between by firing and pressing them under temperature conditions that are 5° C. to 40° C. higher than the melting point of PFA and lower than the melting point of LCP, the insulating substrate being made of one of a fluororesin prepreg and a laminated prepreg formed by laminating a plurality of aforementioned fluororesin prepregs, the both surfaces of the copper foil being smooth and not roughened or blackened.

12. A method for manufacturing a printed-wiring board, wherein a predetermined conductor pattern is formed on the copper-foil surface of the copper-clad laminate obtained by the method according to claim 11.

13. A method for manufacturing a multilayer printed-wiring board, wherein
a plurality of printed-wiring boards are obtained by use of the method according to claim 12, each of the printed-wiring boards being formed by bonding a copper foil to a surface of an insulating substrate,
the plurality of printed-wiring boards are laminated while an LCP/PFA composite film is disposed each between the base material surface of each printed-wiring board and the copper-foil surface of a corresponding printed-wiring board facing the above base material surface, and that
the plurality of printed-wiring boards are bonded to each other by firing and pressing them under conditions from 340° C. to 345° C.
